(19) United States
(12) Patent Application Publication
(10) Pub. No.: US 2009/0122458 A1
(43) Pub. Date: May 14, 2009

(54) EMBOSSED ELECTROSTATIC CHUCK

(75) Inventors: D. Jeffrey Lischer, Acton, MA (US); Dale K. Stone, Lynnfield, MA (US); Lyudmila Stone, Lynnfield, MA (US); David Suuronen, Newburyport, MA (US); Julian G. Blake, Gloucester, MA (US)

Correspondence Address: VARIAN SEMICONDUCTOR EQUIPMENT ASSC., INC., 35 DORY RD., GLOUCESTER, MA, 01930-2297, US

(73) Assignee: VARIAN SEMICONDUCTOR EPUIPMENT ASSOCIATED, INC., Gloucester, MA (US)

(21) Appl. No.: 12/269,394

(22) Filed: Nov. 12, 2008

Related U.S. Application Data
(60) Provisional application No. 60/987,811, filed on Nov. 14, 2007.

(51) Int. Cl. H01L 21/683

(52) U.S. Cl. 361/234

(57) ABSTRACT

An electrostatic chuck includes a layer having a plurality of protrusions to support a workpiece, wherein at least a portion of the layer has a first plurality of the plurality of protrusions. The first plurality of protrusions is spaced to geometrically form a pattern of hexagons. The first plurality of protrusions may be spaced an equal distance from adjacent protrusions and the equal distance may be about 4.0 millimeters from a center of one protrusion to a center of another protrusion. The present disclosure reduces peak mechanical stress levels conventionally present along an edge of each protrusion. Reducing such mechanical stress levels helps reduce backside damage to a supported workpiece, which in turn can reduce the generation of unwanted particles caused by such damage.

### CROSS REFERENCE TO RELATED APPLICATIONS

This application claims the benefit of U.S. provisional patent application Ser. No. 60/987,811, filed Nov. 14, 2007, the teachings of which are incorporated herein by reference.

### FIELD

This disclosure relates to chucks, and more particularly to an embossed electrostatic chuck.

### BACKGROUND

Electrostatic chucks are used to secure and support a workpiece. In one instance, the workpiece may be a semiconductor wafer and may be referred to as such herein. An embossed electrostatic chuck has a plurality of protrusions on the clamping surface of the chuck to support the workpiece. These protrusions may also be referred to as “pins,” “mesas,” “bumps,” or “embossments.” In general, supporting the workpiece on such protrusions may be beneficial since it decreases contact area with the backside of the workpiece compared to a non-embossed clamping surface. It was generally thought that less contact with the backside of the workpiece would generally result in less particle generation which can be critical in some processing applications. In addition, some processing applications may provide a backside cooling gas to cool the backside of the workpiece during processing. The protrusions enable improved gas distribution in such instances.

Turning to FIG. 1, a plan view of an embossed electrostatic chuck 100 known in the prior art is illustrated. The embossed electrostatic chuck 100 has a plurality of protrusions 102 spaced apart in a square pattern 106. The relative size of the protrusions 102 to the chuck 100 has been increased for clarity of illustration. For instance, in one example the chuck may have a total of about 1,200 protrusions when supporting a 300 millimeter (mm) wafer. In this example, each protrusion 102 defining line segments of the square pattern 106 may be spaced 8 mm from each other. Since contact between each protrusion 102 and the backside of a wafer can contribute to generation of unwanted particles, it was generally thought to reduce the number of protrusions and hence increase spacing between the same.

FIG. 2 is a partial cross-sectional view along the line 2-2 of FIG. 1 and illustrates two protrusions 102 supporting a wafer 202. Each protrusion 102 has a cylindrical sidewall 208 and a circular planar top 210 that is polished to produce a level surface. Each protrusion 102 also has a height (H) that may be between about 5-12 micrometers (μm). A diameter (D) of the top 210 may be about 0.4 mm. For a square pattern 106 having a spacing of 8 mm between each line segment of the square pattern, the spacing (S) between protrusions 102 is about 11.3 mm. This longer 11.3 mm spacing (S) is the hypotenuse of a right triangle having 8 mm legs. Each conventional protrusion 102 is fabricated of a hard material such as silicon carbide (SiC) and aluminum oxide (Al₂O₃).

As the wafer 202 is supported by such protrusions 102 against an average clamping pressure, the wafer 202 may deflect or bow over each protrusion producing excessive mechanical stresses at the perimeter 222 of each protrusion 102. The bowing of the wafer 202 is slightly exaggerated in FIG. 2 for clarity of illustration to show the lift of the wafer 202 about the center of each protrusion 102 and the sag of the wafer in between each protrusion 102. This leads to excessive mechanical stresses at the perimeter 222 of each protrusion.

Therefore, a drawback with the conventional protrusions and patterns is excessive bowing of a clamped wafer that leads to excessive mechanical stresses concentrated at the perimeter of each protrusion. This mechanical stress can cause damage to the backside of the wafer 202. Damage to the backside of the wafer can also generate unwanted particles that can contribute to contamination problems.

Accordingly, there is a need for an improved embossed electrostatic chuck which overcomes the above-described inadequacies and shortcomings.

### SUMMARY

According to a first aspect of the disclosure, an electrostatic chuck is provided. The electrostatic chuck includes a layer having a plurality of protrusions to support a workpiece, wherein at least a portion of the layer has a first plurality of the plurality of protrusions. The first plurality of protrusions is spaced to geometrically form a pattern of hexagons.

According to another aspect of the disclosure, a processing apparatus is provided. The processing apparatus includes a process chamber, and an electrostatic chuck positioned within the process chamber. The electrostatic chuck has a plurality of protrusions to support a workpiece for processing, wherein at least a portion of the layer has a first plurality of the plurality of protrusions. The first plurality of protrusions is spaced to geometrically form a pattern of hexagons.

### BRIEF DESCRIPTION OF THE DRAWINGS

For a better understanding of the present disclosure, reference is made to the accompanying drawings, in which like elements are referenced with like numerals, and in which:

FIG. 1 is a plan view of an embossed electrostatic chuck of the prior art;

FIG. 2 is a partial cross sectional view of the embossed electrostatic chuck of FIG. 1 taken along the line 2-2;

FIG. 3 is a plan view of an embossed electrostatic chuck consistent with an embodiment of the disclosure;

FIG. 4 is an enlarged plan view of a selected portion of the chuck of FIG. 3;

FIG. 5 is a partial cross sectional view of the embossed electrostatic chuck of FIG. 3 taken along the line 5-5;

FIGS. 6A and 6B are cross sectional views of protrusions consistent with another embodiment of the disclosure; and

FIGS. 7A-7C are block diagrams of processing apparatuses having an embossed electrostatic chuck consistent with an embodiment of the disclosure.

### DETAILED DESCRIPTION

In general, the present disclosure is directed at an embossed electrostatic chuck that reduces peak mechanical stress levels conventionally present along an edge of each protrusion. Reducing such mechanical stress levels helps reduce backside damage to the supported workpiece, which in turn can reduce the generation of unwanted particles caused by such damage.

The disclosure is described herein with reference to embodiments of an electrostatic chuck for supporting a semiconductor wafer. Those skilled in the art will recognize that an embossed electrostatic chuck consistent with this disclosure may be utilized to support other types of workpieces including, but not limited to, flat panels, solar, and polymer substrates.

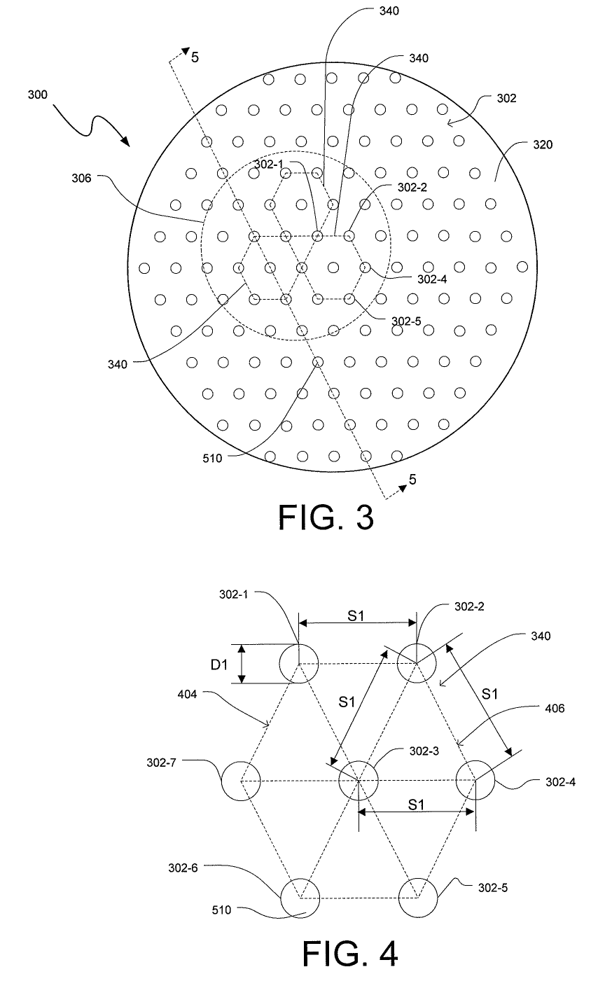

Turning to FIG. 3, a plan view of an embossed electrostatic chuck 300 consistent with an embodiment of the disclosure is illustrated. The chuck 300 has a layer 320 including a plurality of protrusions 302 to support a workpiece such as a semiconductor wafer. The plurality of protrusions 302 may be spaced to geometrically form a pattern of hexagons 340. The relative size of the protrusions 302 to the chuck 300 has been increased for clarity of illustration. For instance, in one embodiment there may be as many as 5,000 protrusions 302 to support a 300 mm wafer.

In the embodiment of FIG. 3, the plurality of protrusions 302 for an entirety of the layer 320 are spaced to form the pattern of hexagons 340. However, in another embodiment only a portion 306 of the layer may have protrusions spaced in such a way where the remaining protrusions may be spaced in other fashions.

FIG. 4 is an enlarged plan view of seven protrusions 302-1, 302-2, 302-3, 302-4, 302-5, 302-6 and 302-7 spaced to geometrically form a hexagon 340. In addition, the protrusions 302-1, 302-2, 302-3, 302-4, 302-5, 302-6 and 302-7 are spaced to form a pattern of equilateral triangles such as equilateral triangle 406 defined by protrusions 302-2, 302-3, and 302-4, and equilateral triangle 404 defined by protrusions 302-1, 302-3, and 302-7. A total of six equilateral triangles have a common vertex to form a hexagon. For example, six equilateral triangles having a common vertex at the center of protrusion 303-3 form the hexagon 340. In addition, a center of each protrusion may be spaced an equal distance or spacing (S1) from adjacent protrusions and the equal distance may be about 4.0 mm. For example, the center of each protrusion 302-1, 302-2, 302-4, 302-5, 302-6 and 302-7 are an equal distance (S1) from the center of the central protrusion 302-3 of FIG. 4.

In addition to the spacing (S1) between adjacent protrusions, each protrusion may have a circular planar contact area 510 as illustrated in FIGS. 3, 4, and 5. The diameter (D1) of the circular planar contact area may be greater than or equal to about 0.75 mm in one embodiment. In another embodiment, the diameter (D1) may be greater than or equal to about 1.0 mm.

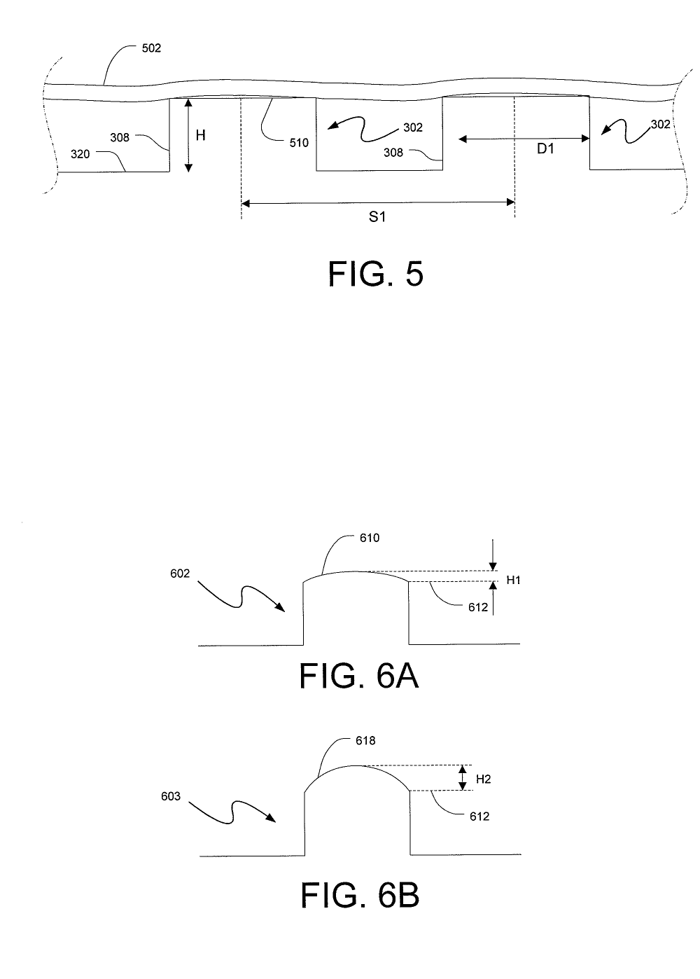

FIG. 5 is a partial cross sectional view of the embossed electrostatic chuck of FIG. 3 taken along the line 5-5 illustrating two protrusions supporting a wafer 502. Each protrusion 302 may have a cylindrical sidewall 308 with a height (H) between about 5 and 12 micrometers (μm). The diameter (D1) and spacing (S1) between protrusions may be as earlier detailed. Advantageously, the hexagonal pattern with a reduced spacing (S1) and enlarged diameter (D1) reduces bowing of the wafer 502 about each protrusion 302 compared to conventional square patterns as illustrated in FIG. 2. Reduced bowing contributes to an increased contact area between the backside of the wafer 502 and the circular planar top 510 of each protrusion 302. The increased contact area of each protrusion enables the clamping force to be spread over a larger area to hence reduce mechanical stress levels at such contact areas. In addition, the reduced spacing (S1) and enlarged diameter (D1) results in a larger aggregate of protrusions having a larger combined contact surface area with which to spread the clamping force.

In another embodiment of the disclosure, the protrusions 302 may be fabricated of materials that are softer than that of harder materials (e.g., SiC and Al₂O₃) of conventional protrusions. Some examples of softer materials include, but are not limited to, silicon dioxide (SiO₂), silicon (Si), silicon nitride (Si₃N₄), and a polyamide. One example of a polyamide is Kapton® “polyimide” provided by Dupont. (“Kapton” is a registered trademark of E.I. du Pont de Nemours and Company.) In order to quantify hardness for a given material, there are differing hardness tests available which generally measure a material's ability to resist plastic deformation from a standard source. One such test is the Vickers hardness test which uses a diamond indenter in the shape of a square based pyramid with an angle of 136° between opposite faces of the indenter. The diamond indenter is forced into the surface of the specimen at a give force (F) and the surface area (A) of the resulting indentation is measured. A hardness number is determined by the ratio F/A. The hardness number may be referred to as a Vickers Pyramid Number or a Diamond Pyramid Hardness Number (DPHN).

The DPHN for a conventional protrusion fabricated of harder materials such as SiC and Al₂O₃ is between about 2500-3000 using tests consistent with ASTM E-92. In contrast, the DPHN for SiN is about 1800, for SiO₂ is about 1200, and for Si is about 600. Polyimide hardness measured by Ultimate Tensile Strength (UTS) is about 0.42 Gpa. Such softer materials also reduce mechanical stresses at the perimeter of the protrusion compared to conventional harder materials. At an average clamping pressure, the protrusions 302 fabricated of the detailed softer materials may compress about their perimeter to reduce mechanical stresses which would normally occur with harder materials.

In one embodiment, the layer 320 of the chuck 300 may be fabricated of the same material as the protrusions 302. To fabricate such a chuck, a mask having a prescribed protrusion pattern may be formed and sandblasting or etching may be carried out to form indentations at those areas not covered by the mask. As a result, those areas covered by the mask remain in the form of the protrusions 302. Alternatively, the protrusions could be fabricated on top of the layer 320 and may be fabricated of a similar or different material compared to the protrusions 302.

According to another aspect of the present disclosure, one or more protrusions may be contoured to encourage additional contact between the protrusion and a backside of a workpiece supported by the protrusion. Turning to FIG. 6A, a protrusion 602 consistent with another embodiment of the disclosure has a curved top 610. A peak of the curved top 610 may be at a height (H1) above a conventional planar top surface 612. FIG. 6B illustrates another embodiment where the protrusion 603 has a curved top 618 at a height (H2) above a conventional flat top surface 612, where H2>H1. The curvature of the top surface may be varied to match an expected deflection of the wafer. As such, mechanical stresses are more evenly distributed across the geometry of the curved surfaces and damage to the backside of the wafer is therefore minimized.

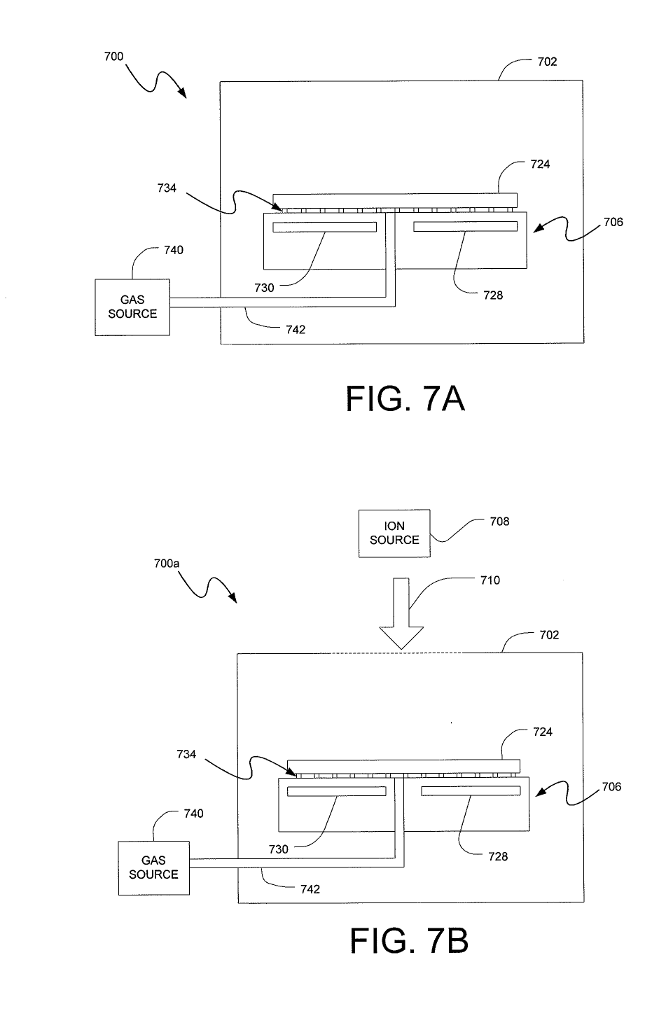

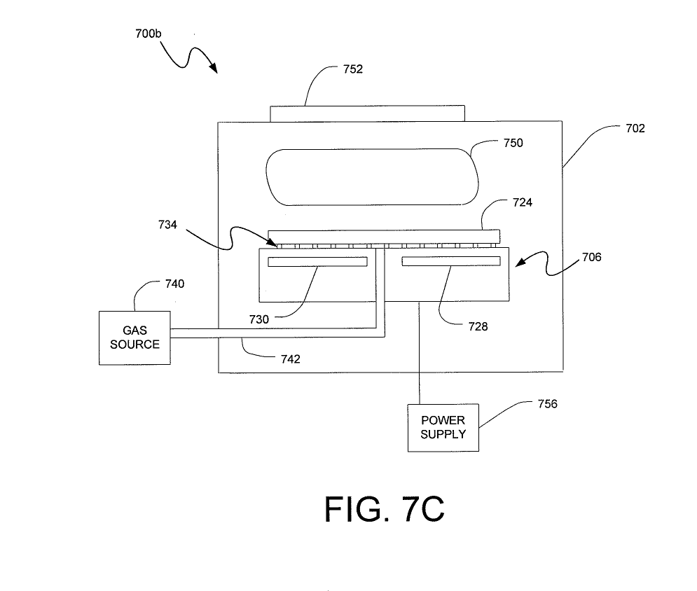

FIG. 7A is a block diagram of a processing apparatus 700 having a process chamber 702 and an electrostatic chuck 706 consistent with an embodiment of the disclosure positioned within the process chamber 702. The processing apparatus 700 may any type of processing apparatus used to retain a workpiece including, but not limited to, etching, deposition, and ion implanting apparatuses.

The electrostatic chuck 706 has a plurality of protrusions 734 to support the workpiece 724 in a clamped position. The electrostatic chuck 706 may include a pair of electrodes 728, 730 that when energized by a power supply (not illustrated) provides an electrostatic attraction force to clamp the workpiece 724 to the chuck 706. A gas source 740 may provide a cooling gas to the backside of the workpiece 724 via one or more conduits 742. The plurality of protrusions 734 further facilitates a uniform distribution of cooling gas beneath the workpiece 724 from the gas source 740.

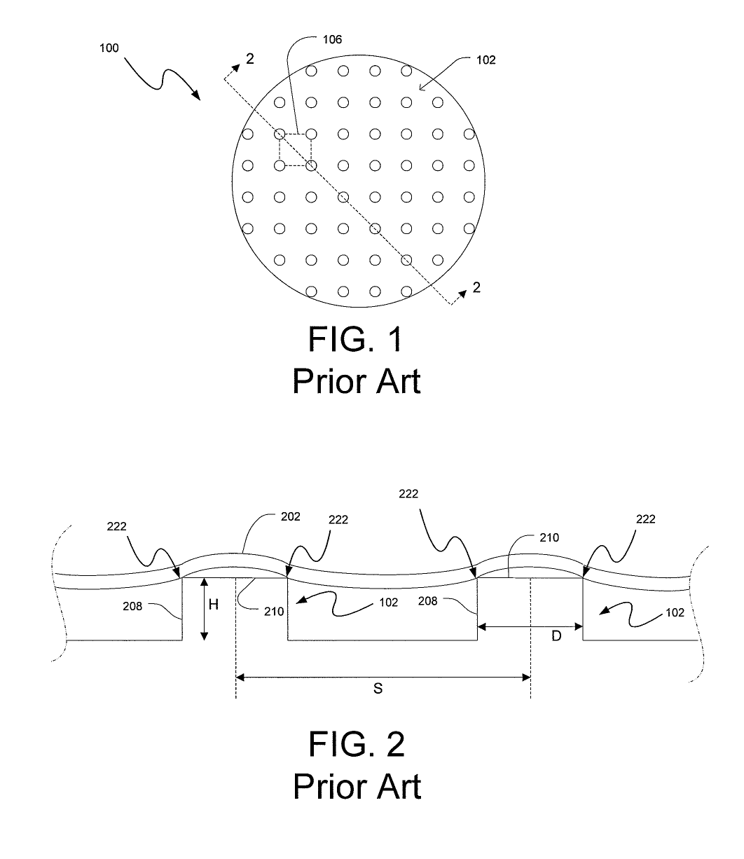

The plurality of protrusions 734 may spaced in a pattern consistent with that of FIGS. 3 to 5. In one embodiment, the electrostatic chuck 706 may support a semiconductor wafer having a 300 millimeter diameter. In one instance, the plurality of protrusions 734 was spaced to geometrically form a pattern of hexagons over an entirety of a clamping surface layer. In addition, each protrusion had circular planar contact area to contact the backside of the wafer in a clamped position where the diameter of each protrusion was 0.75 mm. Each protrusion was also spaced an equal distance of 4.0 mm from the center of each protrusion to a center of another adjacent protrusion. A total number of protrusions 734 were about 5,000 protrusions, which was about 400% more than 1,200 protrusions of a conventional square pattern at 8 mm spacing consistent with the conventional square pattern of FIG. 1. Despite the additional protrusions, there was still less than 4% total contact area between the protrusions and backside of the wafer and no significant impact on cooling efficiency from the gas source 740.

Turning to FIG. 7B, a block diagram of one type of processing apparatus consistent with FIG. 7A is illustrated. In the embodiment of FIG. 7B, the processing apparatus is a beamline ion implanter 700a including an electrostatic chuck 706 consistent with an embodiment of the disclosure positioned within the process chamber 702. The beamline ion implanter 700a includes an ion source 708 configured to generate an ion beam 710. Those skilled in the art will recognize different ion sources such as an indirectly heated cathode source to generate the ion beam 710. The ion beam 710 may be manipulated by differing beamline components (not illustrated) such as a mass analyzer and directed towards the workpiece 724 which may be a semiconductor wafer having a disk shape in one embodiment. In other embodiments, the workpiece may include, but not be limited to, a flat panel, solar, or polymer substrate. The ion beam 710 may be distributed across the workpiece 724 by beam movement, workpiece movement, or a combination of the two. It will be understood by those skilled in the art that the entire path traversed by the ion beam 710 is evacuated during ion implantation.

Turning to FIG. 7C, a block diagram of another type of processing apparatus consistent with FIG. 7A is illustrated. In the embodiment of FIG. 7C, the processing apparatus is a plasma doping apparatus 700b including an electrostatic chuck 706 consistent with an embodiment of the disclosure positioned within the process chamber 702. In one embodiment, the electrostatic chuck 706 may include conductive pins (not shown) for making connection to the workpiece 724.

A dopant gas is provided to process chamber 702 at a desired pressure. The plasma doping apparatus 700b further includes a source 752 configured to generate a plasma 750 from the dopant gas within the process chamber 702. The source 701 may be an RF source and associated antennas or other sources known to those skilled in the art. A power supply 756 may supply a DC or RF bias signal to bias the workpiece 724 via conductive pins of the electrostatic chuck 706. The plasma doping apparatus 700b may further include a shield ring, a Faraday sensor, or other components (not illustrated) known to those skilled in the art. In some embodiments, the plasma doping apparatus 700b may be part of a cluster tool.

In operation, the source 752 is configured to generate the plasma 750 within the process chamber 702. In one embodiment, the source is an RF source that resonates RF currents in at least one RF antenna to produce an oscillating magnetic field. The oscillating magnetic field induces RF currents into the process chamber 702. The RF currents in the process chamber 702 excite and ionize the dopant gas to generate the plasma 750. A bias signal may be provided by the power supply 756 to the workpiece 724 via the electrostatic chuck 706 to attract ions from the plasma 750 towards the workpiece 724. Characteristics of the bias signal may be controlled to provide a desired dose rate and energy. With all other parameters being equal, a greater energy will result in a greater implanted depth.

There is thus provided an electrostatic chuck wherein at least a portion of the chuck has a first plurality of protrusions. The first plurality of protrusions is spaced to geometrically form a pattern of hexagons. In one embodiment, the first plurality of protrusions may also be spaced an equal distance from adjacent protrusions and the equal distance may be about 4.0 millimeters from a center of one protrusion to a center of another protrusion. The present disclosure thus reduces peak mechanical stress levels conventionally present along an edge of each protrusion. Reducing such mechanical stress levels helps reduce backside damage to a supported workpiece, which in turn can reduce the generation of unwanted particles caused by such damage.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes.

Having thus described at least one illustrative embodiment of the invention, various alterations, modifications, and improvements will readily occur to those skilled in the art. Such alterations, modifications, and improvements are intended to be within the scope of the invention. Accordingly, the foregoing description is by way of example only and is not intended as limiting.

What is claimed is:

1. An electrostatic chuck comprising:
a layer having a plurality of protrusions to support a workpiece, wherein at least a portion of the layer has a first plurality of the plurality of protrusions, the first plurality of protrusions spaced to geometrically form a pattern of hexagons.

2. The electrostatic chuck of claim 1, wherein the first plurality of protrusions is further spaced to geometrically form a pattern of equilateral triangles wherein select groupings of six of the equilateral triangles have a common vertex to form one hexagon of the pattern of hexagons.

3. The electrostatic chuck of claim 2, wherein each one of the first plurality of protrusions is spaced an equal distance from adjacent ones of the first plurality of protrusions and the equal distance is about 4.0 millimeters from a center of one protrusion to a center of another protrusion.

4. The electrostatic chuck of claim 3, wherein the first plurality of protrusions have a circular planar contact area to contact a backside of the workpiece in a clamped position, and wherein a diameter of the circular contact area is greater than or equal to about 0.75 millimeters.

5. The electrostatic chuck of claim 3, wherein the first plurality of protrusions have a circular planar contact area to contact a backside of the workpiece in a clamped position, and wherein a diameter of the circular contact area is greater than or equal to about 1.0 millimeters.

6. The electrostatic chuck of claim 1, wherein the plurality of protrusions for an entirety of the layer are spaced to geometrically form the pattern of hexagons.

7. The electrostatic chuck of claim 6, wherein the plurality of protrusions are further spaced to geometrically form a pattern of equilateral triangles wherein select groupings of six of the equilateral triangles have a common vertex to form one hexagon of the pattern of hexagons.

8. The electrostatic chuck of claim 7, wherein each one of the plurality of protrusions is spaced an equal distance from adjacent ones of the plurality of protrusions and the equal distance is about 4.0 millimeters from a center of one protrusion to a center of another protrusion.

9. The electrostatic chuck of claim 8, wherein the plurality of protrusions have a circular contact area to contact a backside of the workpiece in a clamped position, and wherein a diameter of the circular contact area is greater than or equal to about 0.75 millimeters.

10. The electrostatic chuck of claim 6, wherein the plurality of protrusions have a rounded contact area to contact a backside of the workpiece in a clamped position.

11. The electrostatic chuck of claim 6, wherein the plurality of protrusions is fabricated of a material selected from the group consisting of silicon dioxide, silicon, and silicon nitride.

12. The electrostatic chuck of claim 6, wherein the plurality of protrusions are fabricated of a polyamide.

13. A processing apparatus comprising:
a process chamber; and
an electrostatic chuck positioned within the process chamber, the electrostatic chuck having a plurality of protrusions to support a workpiece for processing, wherein at least a portion of the layer has a first plurality of the plurality of protrusions, the first plurality of protrusions spaced to geometrically form a pattern of hexagons.

14. The processing apparatus of claim 13, further comprising an ion source to generate an ion beam to be directed towards the workpiece.

15. The processing apparatus 13, wherein the first plurality of protrusions is further spaced to geometrically form a pattern of equilateral triangles wherein select groupings of six of the equilateral triangles have a common vertex to form one hexagon of the pattern of hexagons.

16. The processing apparatus 15, wherein each one of the first plurality of protrusions is spaced an equal distance from adjacent ones of the first plurality of protrusions and the equal distance is about 4.0 millimeters from a center of one protrusion to a center of another protrusion.

17. The processing apparatus 16, wherein the first plurality of protrusions have a circular contact area to contact a backside of the workpiece in a clamped position, and wherein a diameter of the circular planar contact area is greater than or equal to about 0.75 millimeters.

18. The processing apparatus of claim 13, further comprising a source to generate a plasma within the process chamber and wherein ions from the plasma are attracted to the workpiece in response to a bias signal provided to the workpiece via the electrostatic chuck.
